(19) United States
(12) Patent Application Publication
(10) Pub. No.: US 2007/0226559 A1
(43) Pub. Date: Sep. 27, 2007

(54) MULTIMEDIA DEVICE TESTING METHOD

(75) Inventor: PAI-CHEN LIU, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/608,799

(22) Filed: Dec. 9, 2006

(30) Foreign Application Priority Data
Mar. 10, 2006 (CN) 200610034355.8

(51) Int. Cl. G01R 31/28

(52) U.S. Cl. 714/724

(57) ABSTRACT

A multimedia device testing method is provided. The multimedia device testing method includes providing test files of each test signal according to parameters of each test signal via a computer; combining the files of each test signal into one file with a composite test signal via the computer; compiling the file of the composite test signal as an object executable file via the computer; and executing the object executable file via a generator for generating a frame of the composite test signal, and the composite test signal is then transmitted to the multimedia device, and used for testing the multimedia device.

### BACKGROUND OF THE INVENTION

1. Field of the Invention

The present invention relates to a testing method, and particularly to a multimedia device testing method.

2. Related of Prior Art

A system test is necessary after manufacture of a multimedia device, such as a set top box (STB), a wireless television, or a video phone, is manufactured. The system test includes testing quality of a video signal processed by the multimedia device. That is, a signal generator generates a test signal and transmits the test signal to the multimedia device to process the test signal. Then a video signal analyzer analyzes the test signal processed by the multimedia device. At present, most countries around the world follow one of three main video broadcast standards, which are NTSC (National Television Standards Committee), PAL (Phase Alternating Line), and SECAM (Sequential Color and Memory). The test signals respectively correspond to each of the video broadcast standards.

Table 1 lists 24 types of test signals of the NTSC standard. Each of the test signals corresponds to one testing function. For example, the pulse bar test signal is used to test the amplitude, timing, and distortion of the video signal processed by the multimedia device.

TABLE 1

| Sequence Number | Name of Scan Line |
|---|---|
| 1 | Color Bar 75% |
| 2 | IRE 100 |
| 3 | Grey Wind |
| 4 | (Sin x)/x |
| 5 | Red 100 |
| 6 | Ramp |
| 7 | Pulse Bar |
| 8 | RBB |
| 9 | Sweep |
| 10 | IRE 0 |
| 11 | 5 Step |
| 12 | Color Bar 100% |
| 13 | FCC Composite |
| 14 | N7 Composite |
| 15 | Modulation 5 Step |
| 16 | Modulation 10 Step |
| 17 | Multi Burst |
| 18 | Modulation Ramp |
| 19 | 8 MHz Sweep |
| 20 | Modulation Ped |
| 21 | Multi Pulse |
| 22 | Horizontal Line |
| 23 | IWQ |
| 24 | Vertical Line |

Since there are 24 tests need to perform one at a time, many of testing steps involve in any testing process. Therefore, a heretofore unaddressed need exists in the industry to reduce the number of steps required to test multimedia devices.

### SUMMARY OF THE INVENTION

A multimedia device testing method is provided. The multimedia device testing method includes providing test files of each test signal according to parameters of each test signal via a computer; combining the files of each test signal into one file with a composite test signal via the computer; compiling the file of the composite test signal to an object executable file via the computer; and executing the object executable file via a generator for generating a frame of the composite test signal, which is then transmitted to the multimedia device for testing the multimedia device.

Other objectives, advantages and novel features of the present invention will be drawn from the following detailed description of preferred embodiments of the present invention with the attached drawings, in which:

### BRIEF DESCRIPTION OF THE DRAWINGS

FIG. 1 is a flowchart of testing a multimedia device in accordance with an exemplary embodiment of the present invention.

### DETAILED DESCRIPTION OF THE INVENTION

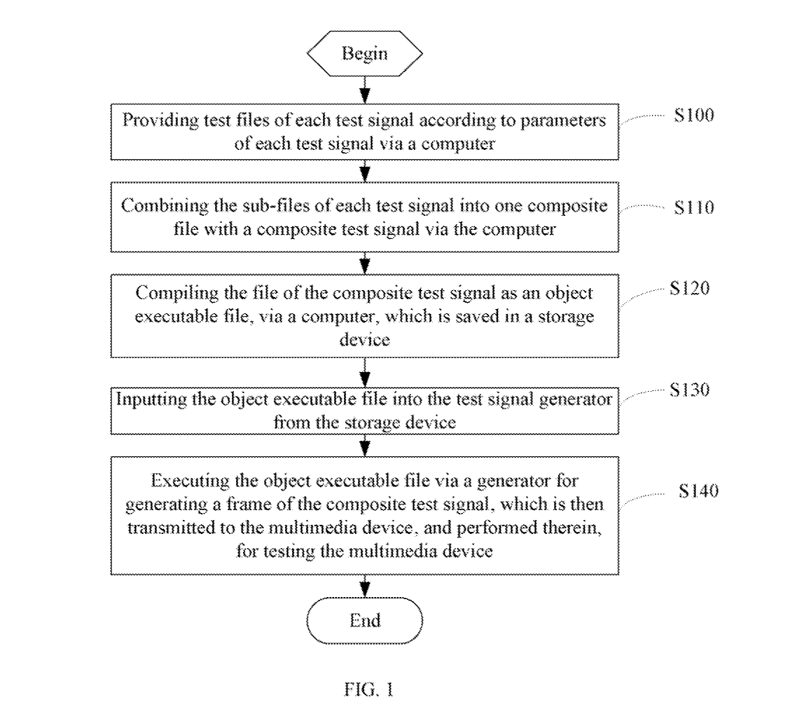

FIG. 1 is a flowchart of testing a multimedia device in accordance with an exemplary embodiment of the present invention.

In step S100, test files of each test signal according to parameters of each test signal via a computer are provided. In this exemplary embodiment, the file of each test signal includes three parameters, which are sync level, color burst, and white level all represented by IRE. In the embodiment, the file extensions of the files are all “.EQN”. The IRE is institute of radio engineers, and is a type of unit measurement used on a television waveform monitor for measuring signal level.

For example, a time sequence of the sync level of the IRE 100 test signal is 4.7 μs, and an amplitude of that is 40 IRE (286 mV). The time sequence of the color burst of the IRE 100 test signal is 2.5 μs, the amplitude of that is 40 IRE (286 mV), and the sub-carrier frequency of that is 3.579545 MHz. The white level of the IRE 100 test signal only includes the white level, and the amplitude of that is 100 IRE (714 mV). Each parameter of the IRE 100 test signal is defined in the RS-170A standard, which is a standard composite video format used in the United States. The parameters and the files of other test signals are provided using the same approach as the IRE 100 test signal.

In step S110, the computer combines the sub-files of each test signal into one composite file with a composite test signal. In the embodiment, the file extension of the composite file is “.MEM”.

In this exemplary embodiment, 24 sub-files of each of the test signals are combined into one composite file with a composite test signal via the computer. For example, an NTSC interlace video includes an odd field of 262 scan lines, and an even field of 263 scan lines. Typically, the first 20 scan lines of the odd field and the even field respectively are not employed in a test, because those scan lines are vertical blanking interval scan lines, which are not shown on a screen. Furthermore, when a video test is performed, there is no difference between employing the scan lines of the odd field and the even field. Therefore, the first 20 scan lines of the odd field and the even field are not employed in the video test in this exemplary embodiment. In other words, only the 21^{st} to the 262^{nd} scan lines of the odd field, as shown in table 2, are tested.

Twenty four types of test signals can be combined into a composite file with composite test signal according to table 2. Namely, in this example, after performing the steps of FIG. 1, twenty-four sub-files of each of the test signals are combined into one composite file with a composite test signal via the computer. In this embodiment, the 21^{st} to the 30^{th} scan lines, the 31^{st} to the 40^{th} scan lines, the 41^{st} to the 50^{th} scan lines, the 51^{st} to the 60^{th} scan lines, the 61^{st} to the 70^{th} scan lines, the 71^{st} to the 80^{th} scan lines, are employed to respectively display the Color Bar 75% test signal, the IRE 100 test signal, the GreyWind test signal, the Sin (x/x) test signal, the Red 100 test signal, and the Ramp test signal.

The 81^{st} to the 90^{th} scan lines, the 91^{st} to the 100^{th} scan lines, the 101^{st} to the 110^{th} scan lines, the 111^{st} to the 120^{th} scan lines, the 121^{st} to the 130^{th} scan lines, the 131^{st} to the 140^{th} scan lines, are employed to respectively display the Pulse Bar test signal, the RBB test signal, the 6 MHz Sweep test signal, the IRE 0 test signal, the 5 Step test signal, and the Color Bar 100% test signal.

The 81^{st} to the 90^{th} scan lines, the 141^{st} to the 150^{th} scan lines, the 151^{st} to the 160^{th} scan lines, the 161^{st} to the 170^{th} scan lines, the 171^{st} to the 180^{th} scan lines, the 191^{st} to the 200^{th} scan lines, are employed to respectively display the FCC Composite test signal, the N7 Composite test signal, the Modulation 5 Step test signal, the Modulation 10 Step test signal, the Multi Burst test signal, and the Modulation Ped test signal.

The 201^{st} to the 210^{th} scan lines, the 211^{st} to the 220^{th} scan lines, the 221^{st} to the 230^{th} scan lines, the 231^{st} to the 240^{th} scan lines, the 241^{st} to the 250^{th} scan lines, the 251^{st} to the 262^{nd} scan lines, are employed to respectively display the 8 MHz Sweep test signal, the Modulation Red test signal, the Multi Pulse test signal, the Horizontal Line test signal, the IWQ test signal, and the Vertical Line test signal.

TABLE 2

| Sequence Number | Scan Line | Name of Scan Line |
|---|---|---|
| 1 | 21~30 | Color Bar 75% |
| 2 | 31~40 | IRE 100 |
| 3 | 41~50 | GreyWind |
| 4 | 51~60 | (Sin x)/x |
| 5 | 61~70 | Red 100 |
| 6 | 71~80 | Ramp |
| 7 | 81~90 | Pulse Bar |
| 8 | 91~100 | RBB |
| 9 | 101~110 | 6 MHz Sweep |
| 10 | 111~120 | IRE 0 |
| 11 | 121~130 | 5 Step |
| 12 | 131~140 | Color Bar 100% |
| 13 | 141~150 | FCC Composite |
| 14 | 151~160 | N7 Composite |
| 15 | 161~170 | Modulation 5 Step |
| 16 | 171~180 | Modulation 10 Step |
| 17 | 181~190 | Multi Burst |
| 18 | 191~200 | Modulation Ped |
| 19 | 201~210 | 8 MHz Sweep |
| 20 | 211~220 | Modulation Red |
| 21 | 221~230 | Multi Pulse |
| 22 | 231~240 | Horizontal Line |
| 23 | 241~250 | IWQ |
| 24 | 251~262 | Vertical Line |

A file of the composite test signal, which includes multiple programs or sub-files can be designed according to the table 2. The programs can be written in a C language or a script language and so on.

In step S120, the composite file of the composite test signal is compiled as an object executable file, via a computer, which is saved in a storage device.

In detail, firstly, the file of the composite test signal is compiled as an object executable file via a computer; secondly, a path and a name are set for the object executable file via the computer; lastly, the object executable file is saved in a storage device, such as a floppy disc, a flash memory, or a compact disc.

In step S130, the object executable file is input into a test signal generator from the storage device. In this embodiment, the object executable file is input into the test signal generator from the floppy disc.

In step S140, the generator executes the object executable file for generating a frame of the composite test signal, which is then transmitted to the multimedia device, and used for testing the multimedia device. In this embodiment, the frame of the composite test signal includes parameters of each test signal.

The multimedia device testing method of the present invention tests the multimedia device by transmitting a frame of the composite test signal instead of transmitting a plurality of types of test signals one after the other. Therefore, testing time is reduced, and testing efficiency is improved.

The description of the present invention has been presented for purposes of illustration and description, and is not intended to be exhaustive or limited to the invention in the form disclosed. Many modifications and variations will be apparent to those of ordinary skill in the art. The embodiment was chosen and described in order to best explain the principles of the invention, the practical application, and to enable others of ordinary skill in the art to understand the invention for various embodiments with various modifications as are suited to the particular use contemplated.

What is claimed is:

1. A multimedia device testing method, comprising:
providing test files of each test signal according to parameters of each test signal via a computer;
combining the files of each test signal into one composite file with a composite test signal via the computer;
compiling the file of the composite test signal as an object executable file via the computer; and
executing the object executable file via a generator for generating a frame of the composite test signal, and the composite test signal is then transmitted to the multimedia device, and used for testing the multimedia device.

2. The multimedia device testing method as recited in claim 1, further comprising a step of setting a path and a name for the object executable file via the computer.

3. The multimedia device testing method as recited in claim 1, further comprising a step of inputting the object executable file into the test signal generator from the storage device.

4. The multimedia device testing method as recited in claim 1, wherein the file of each test signal comprises a sync level.

5. The multimedia device testing method as recited in claim 4, wherein the file of each test signal further comprises a color burst.

6. The multimedia device testing method as recited in claim 5, wherein the file of each test signal further comprises a white level.

7. The multimedia device testing method as recited in claim 1, wherein the frame of the composite test signal comprises parameters of each test signal.

8. A method to test multimedia devices, comprising steps of:
providing corresponding test files of test signals, each of which is adapted for an exclusively predefined test of multimedia devices, according to parameters of said each of test signals;
combining said test files into a composite file to form a composite test signal; and
generating a viewable frame of said composite test signal based on said composite file so that at least two of said test signals are viewable through said frame simultaneously on said multimedia devices.

9. The method as recited in claim 8, further comprising a step of compiling said composite file of said composite test signal to an object executable file before said frame is generated based on said executable file.

10. A method to test multimedia devices, comprising steps of:
providing at least two test signals adapted for corresponding different predefined tests of multimedia devices;
combining said at least two test signals into a composite test signal; and
generating a viewable frame of said composite test signal so that said at least two test signals are viewable through said frame simultaneously on said multimedia devices.
